(19) United States
(12) Patent Application Publication
(10) Pub. No.: US 2017/0170312 A1
(43) Pub. Date: Jun. 15, 2017

(54) HIGH VOLTAGE DMOS AND THE METHOD FOR FORMING THEREOF

(71) Applicant: Monolithic Power Systems, Inc., San Jose, CA (US)

(72) Inventors: Ji-Hyoung Yoo, Cupertino, CA (US); Yanjie Lian, Chengdu (CN); Daping Fu, Chengdu (CN)

(21) Appl. No.: 14/970,537

(22) Filed: Dec. 15, 2015

(51) Int. Cl. H01L 29/78; H01L 29/66; H01L 29/08; H01L 29/40; H01L 29/10

(52) U.S. Cl. CPC H01L 29/7823; H01L 29/405; H01L 29/1095; H01L 29/0882; H01L 29/0865; H01L 29/0886; H01L 29/66681

(57) ABSTRACT

A high voltage DMOS device using conventional silicon BCD (Bipolar CMOS DMOS) technology has a P-type buried layer and an N-type buried layer, a first epitaxial layer and a second epitaxial layer. The high voltage DMOS device is characterized in high breakdown voltage, good robustness and low Ron through controlling the thickness of the epitaxial layers, the dose and forming energy of the buried layers. In addition, the high voltage DMOS may further has a shallow drain region to further improve robustness.

### FIELD

The present invention relates to power devices, more specifically, the present invention relates to high voltage DMOS devices.

### BACKGROUND

DMOS devices are popularly used in switching mode power supplies because of the good performance of the device. Ideally, low side DMOS drain is required to be fully isolated from substrate, because fully isolated drain would collect electrons emitted by the drain and prevent them from flowing to nearby N-wells. Electrons from low side DMOS drain could be emitted when its voltage goes below the substrate potential due to switched inductive load. Electron emission such as stray electrons in the substrate is undesirable for it may cause latch up and circuit malfunction.

Conventional technology uses an N-well moat (or guard ring) around low side DMOS devices to collect stray electrons, hence it reduces the effect of electron injection. However, this method consumes silicon area, and is not that effective.

Recently some technologies offer fully isolated drain structures. One example is using silicon on insulator (SOI). However, it has a potential issue of weak thermal robustness. Also SOI is very expensive to achieve.

Another approach is using silicon process with deep n-buried layer (NBL) and p-buried layer (PBL). However, this approach has a low breakdown voltage which has a limitation for high voltage applications (e.g., for 45V or 60V application). In addition, it has poor electrical robustness problem.

### SUMMARY

A high voltage DMOS device using conventional silicon BCD (Bipolar CMOS DMOS) technology is provided. The high voltage DMOS device have a P-type buried layer and an N-type buried layer, a first epitaxial layer and a second epitaxial layer. By controlling the thickness of the epitaxial layers, the dose and forming energy of the buried layers, the high voltage DMOS device has high breakdown voltage, good robustness and low Ron. The high voltage DMOS further has a shallow drain region, which further improves robustness.

### BRIEF DESCRIPTION OF THE DRAWINGS

FIG. 1 schematically shows a cross-section view of a high voltage DMOS 100 in accordance with an embodiment of the present invention.

FIG. 2 schematically shows a cross-section view of a high voltage DMOS 200 in accordance with an embodiment of the present invention.

FIG. 3 schematically shows a cross-section view of forming an N-type buried layer 102 in a semiconductor substrate 101 with P-type doping to form a high voltage DMOS device in accordance with an embodiment of the present invention.

FIG. 4 schematically shows a cross-section view of forming a first epitaxial layer 103 on the substrate 101 in accordance with an embodiment of the present invention.

FIG. 5 schematically shows a cross-section view of forming a link layer 119 with N-type doping in the first epitaxial layer 103 in accordance with an embodiment of the present invention.

FIG. 6 schematically shows a cross-section view of forming a P-type buried layer 104 in the first epitaxial layer 103 in accordance with an embodiment of the present invention.

FIG. 7 schematically shows a cross-section view of forming a second epitaxial layer 105 with P-type doping on the first epitaxial layer 103 in accordance with an embodiment of the present invention.

FIG. 8 schematically shows a cross-section view of forming a drain drift region 106 with N-type doping in the second epitaxial layer 105 in accordance with an embodiment of the present invention.

FIG. 9 schematically shows a cross-section view of forming a field region 107 formed in the second epitaxial layer 105 in accordance with an embodiment of the present invention.

FIG. 10 schematically shows a cross-section view of forming a thermal oxide field plate 108 on part of the drain drift region 106 in accordance with an embodiment of the present invention.

FIG. 11 schematically shows a cross-section view of forming P-type well region 117 and N-type well region 118 in the second epitaxial layer 105 in accordance with an embodiment of the present invention.

FIG. 12 schematically shows a cross-section view of forming thin gate oxide on active area of the second epitaxial layer 105 in accordance with an embodiment of the present invention.

FIG. 13 schematically shows a cross-section view of forming a gate poly 109 on the thin gate oxide and on the thermal oxide field plate 108 in accordance with an embodiment of the present invention.

FIG. 14 schematically shows a cross-section view of forming a body region 110 with P-type doping in the second epitaxial layer 105 in accordance with an embodiment of the present invention.

FIG. 15 schematically shows a cross-section view of forming a shallow drain region 111 with N-type doping in the drain drift region 106 in accordance with an embodiment of the present invention.

FIG. 16 schematically shows a cross-section view of forming a drain pickup region 112 with N-type doping in the shallow drain region 111, a source pickup region 113 with N-type doping and a body pickup region 114 with P-type doping in the body region 110, a plurality of CMOS pickup regions 120 with P-type doping and 121 with N-type doping in the well regions 118 and 117, respectively in accordance with an embodiment of the present invention.

FIG. 17 schematically shows a cross-section view of forming a plurality of electrodes contacted with the pickup regions and with the gate poly in accordance with an embodiment of the present invention.

The use of the similar reference label in different drawings indicates the same of like components.

### DETAILED DESCRIPTION

Embodiments of circuits for high voltage DMOS are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

FIG. 1 schematically shows a cross-section view of a high voltage DMOS 100 in accordance with an embodiment of the present invention. In the example of FIG. 1, the high voltage DMOS 100 comprises: a substrate 101 with P-type doping; an N-type buried layer (NBL) 102; a first epitaxial layer (1^{st} EPI) 103 with P-type doping formed on the substrate 101; a P-type buried layer (PBUR) 104 formed in the first epitaxial layer 103, wherein the entire P-type buried layer 104 is on top of the N-type buried layer 102 and on part of the N-type buried layer 102; a second epitaxial layer (2^{nd} EPI) 105 with P-type doping formed on the first epitaxial layer 103; a drain drift region (LNW) 106 with N-type doping formed in the second epitaxial layer 105, wherein the drain drift region 106 is on part of the P-type buried layer 104; a field region 107 formed in the second epitaxial layer 105; a thermal oxide field plate 108 formed on part of the drain drift region 106; a P-type well region (PWL) 117 formed in the second epitaxial layer 105, wherein the P-type well region 117 is adjacent to the drain drift region 106; a gate oxide formed on any active area (other than on the field region 107); a gate poly 109 formed on the gate oxide and on the thermal oxide field plate 108; a body region (DPB) 110 with P-type doping formed in the second epitaxial layer 105, wherein the body region 110 is adjacent to the drain drift region 106; a shallow drain region (SNW) 111 with N-type doping formed in the drain drift region 106; a drain pickup region (N+) 112 with N-type doping formed in the shallow drain region 111; a source pickup region (N+) 113 with N-type doping and a body pickup region (P+) 114 with P-type doping formed in the body region 110, wherein the source pickup region 113 and the body pickup region 114 are adjacent to each other; a drain electrode 115 contacted with the drain pickup region 112; a source electrode 116 contacted with the source pickup region 113 and with the body pickup region 114; and a gate electrode (not shown in the figure due to the direction of the cross section of the high voltage DMOS 100) contacted with the gate poly 109.

In the example of FIG. 1, the field region 107 is formed as shallow trench isolation (STI) structure. However, in other embodiments, the field region 107 may be formed using field oxidation.

In one embodiment, the P-type buried layer 104 acts as a bottom layer to isolate the drain drift region 106. In addition, the P-type buried layer 104 creates RESURF action to increase the breakdown voltage in a given drift region length, which helps to improve Ron*A (wherein A represents the top area of the device). The dose and forming energy of the P-type buried layer 104 is critical. High dose may lead to low the breakdown voltage and epitaxial silicon defect. But low dose may cause the isolation to not work and lead to increased parasitic NPN's beta and P-type buried layer 104's junction resistance, which hampers the high voltage DMOS' robustness.

In one embodiment, the P-type buried layer 104 has forming energy in the range of 200 KeV-1 MeV; and has a dose in a range of 5×10¹¹-4×10¹³ atoms per cubic centimeter.

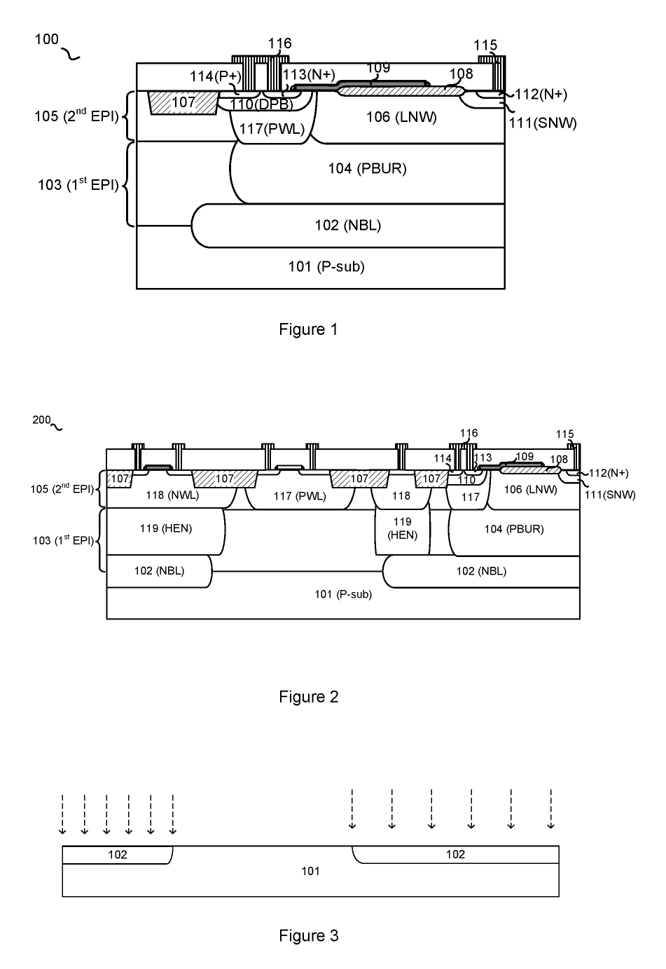

FIG. 2 schematically shows a cross-section view of a high voltage DMOS 200 in accordance with an embodiment of the present invention. The high voltage DMOS 200 in FIG. 2 is similar to the high voltage DMOS 100 in FIG. 1, with a difference that the high voltage DMOS 200 in FIG. 2 further comprises: an N-type well region (NWL) 118 formed in the second epitaxial layer 105, wherein the N-type well region 118 is close to the P-type well region 117; and a link layer 119 with N-type doping formed in the first epitaxial layer 103. The link layer 119 is the contact layer of the N-type buried layer 102 and the N-type well region 118, which is formed between the first buried layer 102 and the N-type well region 118.

In one embodiment, the first epitaxial layer 103 has a thickness in a range of 4 μm-10 μm. The thickness of the first epitaxial layer 103 is critical to reduce parasitic NPN's beta and P-type buried layer 104's junction resistance. Thicker epitaxial layer leads to low beta and low P-type buried layer 104's junction resistance. But if the epitaxial layer is too thick, the link layer 119 may have a high resistance.

In one embodiment, the second epitaxial layer 105 has a thickness in the range of 1.2 μm-4.0 μm. The thickness of the second epitaxial layer 105 is critical to prevent parasitic NPN to be turned on. If the second epitaxial layer 105 is too thin, the drain drift region 106 would touch the second buried layer 104, and the breakdown would happen between 106 and 104. Then a large hole current from impact ionization would flow through the P-type buried layer 104 and cause voltage drop inside of the P-type buried layer 104. This will turn on parasitic NPN's Emitter (102)-Base (104) junction, and it could blow up the device. However, if the second epitaxial layer 105 is too thick, the link layer 119 may have a high resistance.

In one embodiment, the shallow drain region 111 is formed to create gradient drift region to improve robustness.

FIGS. 3-17 schematically show cross-section views of a semiconductor substrate with P-type doping undergoing a process for forming a high voltage DMOS device in accordance with an embodiment of the present invention.

As shown in FIG. 3, the process includes forming an N-type buried layer 102 in the substrate 101.

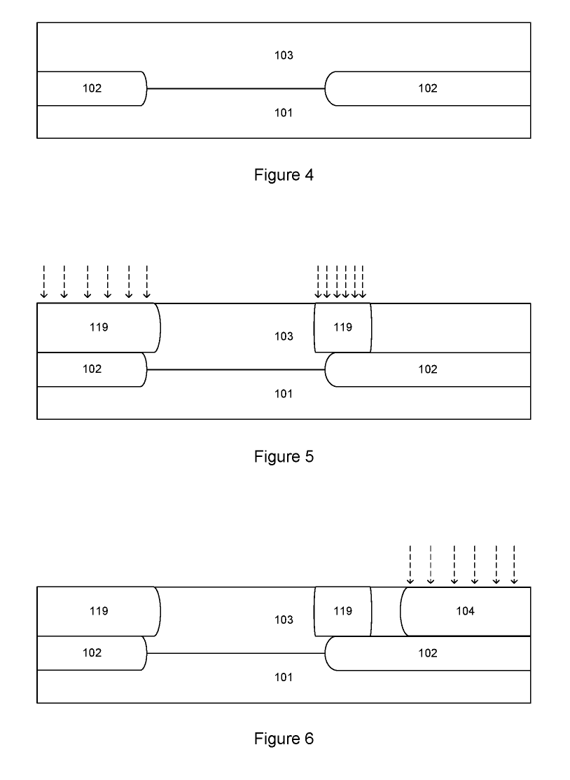

As shown in FIG. 4, the process includes forming a first epitaxial layer 103 on the substrate 101. The first epitaxial layer 103 has a recommended thickness in a range of 4 μm-10 μm. In one embodiment, the first epitaxial layer 103 may be formed by deposition technique such as chemical vapor deposition (CVD), plasma enhance chemical vapor deposition (PECVD), atomic layer deposition (ALD), liquid phase epitaxy, and/or other suitable deposition techniques. In one embodiment, the epitaxial layer 103 may be doped with P-type impurities.

As shown in FIG. 5, the process includes forming a link layer 119 with N-type doping in the first epitaxial layer 103. The link layer 119 contacts the N-type buried layer 102 at the bottom side. In one embodiment, the link layer 119 may be formed by implantation.

As shown in FIG. 6, the process includes forming a P-type buried layer 104 in the first epitaxial layer 103, wherein the entire P-type buried layer 104 is on top of and on part of the N-type buried layer 102. In one embodiment, the P-type buried layer 104 may be formed by implantation. The P-type buried layer 104 has a recommended forming energy in a range of 200 KeV-1 MeV; and has a recommended dose in a range of 5×10¹¹-4×10¹³ atoms per cubic centimeter. Also, the thermal treatment of the link layer 119 and the P-type buried layer 104 is required in order to cure silicon damage from high energy implantation.

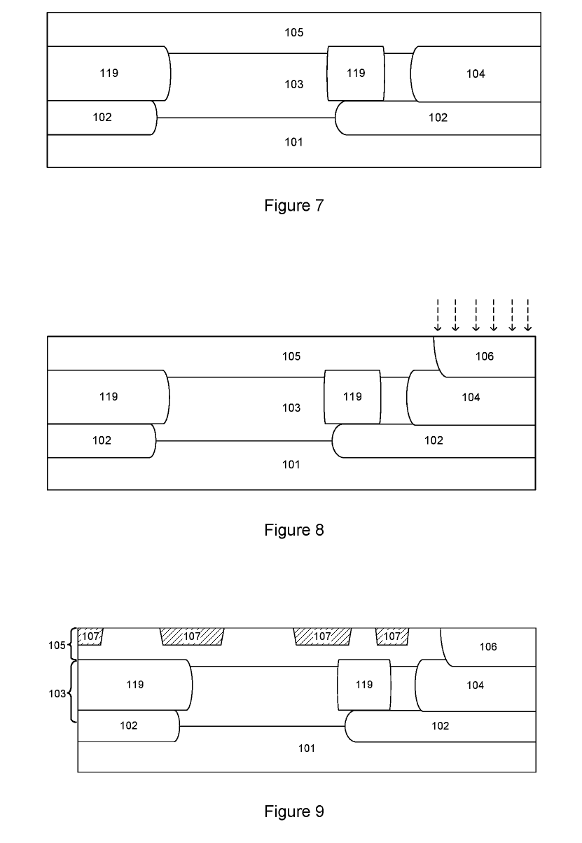

As shown in FIG. 7, the process includes forming a second epitaxial layer 105 with P-type doping on the first epitaxial layer 103. The second epitaxial layer 105 has a recommended thickness in a range of 1.2 μm-4.0 μm.

As shown in FIG. 8, the process includes forming a drain drift region 106 with N-type doping in the second epitaxial layer 105, wherein the drain drift region 106 is on part of the second buried layer 104. In one embodiment, the drain drift region 106 may be formed by implantation technology. Adequate thermal process to anneal implant damage and to drive-in the drain drift region 106 can be added.

As shown in FIG. 9, the process includes forming a field region 107 formed in the second epitaxial layer 105. In one embodiment, the field region 107 is formed as shallow trench isolation (STI) structure. However, in other embodiments, the field region 107 may be formed using field oxidation.

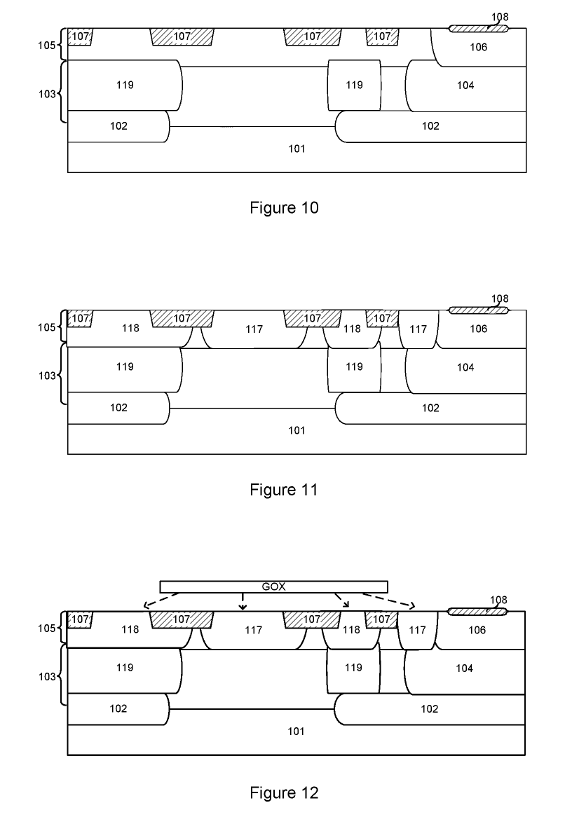

As shown in FIG. 10, the process includes forming a thermal oxide field plate 108 on part of the drain drift region 106.

As shown in FIG. 11, the process includes forming P-type well region 117 and N-type well region 118 in the second epitaxial layer 105. In one embodiment, the well regions may be formed by implantation technology. Adequate thermal process to anneal implant damage and to drive-in the well regions can be added.

As shown in FIG. 12, the process includes forming thin gate oxide on active area (outside of the field region 107) of the second epitaxial layer 105. In one embodiment, the thin gate oxide may be formed by dry oxidation technology. In one embodiment, the thin gate oxide thickness ranges from 70 A to 250 A.

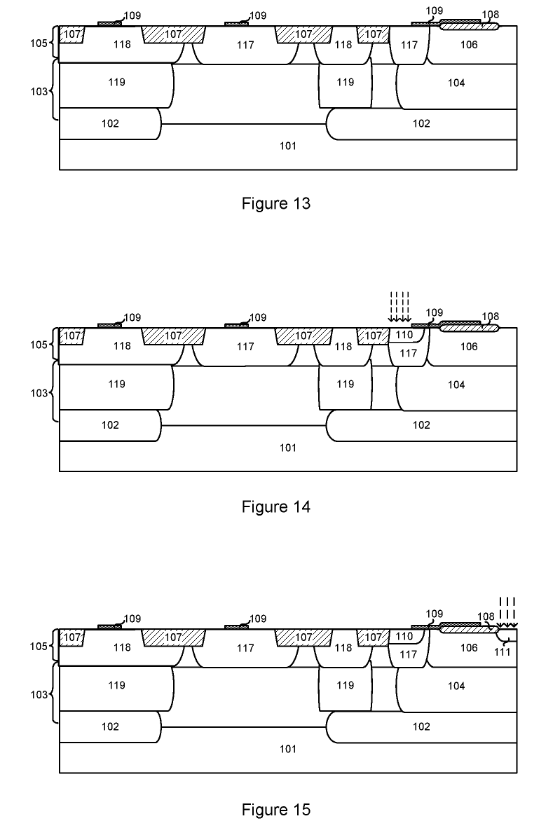

As shown in FIG. 13, the process includes forming a gate poly 109 on the thin gate oxide and on the thermal oxide field plate 108.

As shown in FIG. 14, the process includes forming a body region 110 with P-type doping in the second epitaxial layer 105, wherein the body region 110 is adjacent to the drain drift region 106. In this embodiment, the body region 110 is self-aligned by gate poly 109. In one embodiment, the body region 110 can be used as Bipolar transistor's Base region. In one embodiment, the body region 110 is formed by conventional implantation technology. Adequate thermal process to anneal implant damage and to drive-in the body 110 can be added.

As shown in FIG. 15, the process includes forming a shallow drain region 111 with N-type doping in the drain drift region 106. In one embodiment, the shallow drain region 111 is formed by implantation technology. Adequate thermal process to anneal implant damage and to drive-in the shallow drain region 111 can be added.

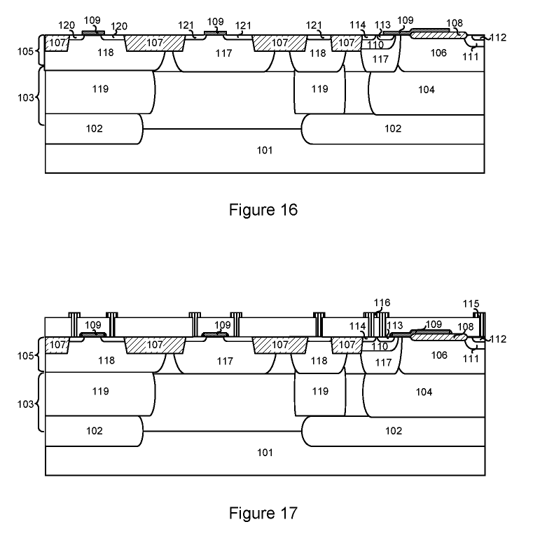

As shown in FIG. 16, the process includes forming a drain pickup region 112 with N-type doping in the shallow drain region 111, a source pickup region 113 with N-type doping and a body pickup region 114 with P-type doping in the body region 110, a plurality of CMOS pickup regions 120 with P-type doping and 121 with N-type doping in the well regions 118 and 117, respectively, and wherein the source pickup region 113 and the body pickup region 114 are adjacent to each other. In one embodiment, the pickup regions are formed by implantation technology. Adequate thermal process to anneal implant damage and to drive-in the pickup regions can be added.

As shown in FIG. 17, the process includes forming a plurality of electrodes (e.g., drain electrode 115 and source electrode 116) contacted with the pickup regions and with the gate poly.

In convention technologies' low side DMOS, unwanted electrons from Drain (106) would be injected to substrate (101) when drain potential goes below substrate potential; and it could flow into nearby nwell body (118), causing device malfunction. Unlike the conventional technology, several embodiments of the foregoing low side DMOS device reduce substrate injection (electron flow into substrate) almost to zero, which highly eases design. In the present invention, the unwanted electrons from drain (106) would be collected by surrounding N-tubs, (e.g., 118, 119 and 102), so device malfunction risk caused by stray electrons would be greatly reduced. In addition, no moat (guard ring) is needed, which substantially saves die area. Furthermore, several embodiments of the foregoing DMOS device provide low Ron*A and high breakdown voltage in a given area by RESURF action from 104), which further saves overall die area.

This isolated drain feature is actualized on some low voltage rating DMOS (for example, below 30V), but it is very hard to make it on higher voltage rating DMOS technologies because of the poor robustness in higher voltage isolated DMOS structure. The present invention makes it possible with optimum epitaxial thickness control (both the first and second epitaxial layer) and doping/thickness control of N-type buried layer (102) and P-type buried layer (104).

This written description uses examples to disclose the invention, including the best mode, and also to enable a person skilled in the art to make and use the invention. The patentable scope of the invention may include other examples that occur to those skilled in the art.

1. A high voltage DMOS, comprising:
a substrate with P-type doping;
an N-type buried layer;
a first epitaxial layer with P-type doping formed on the substrate;
a P-type buried layer formed in the first epitaxial layer, wherein the entire P-type buried layer is on top of and on part of the N-type buried layer;
a second epitaxial layer with P-type doping formed on the first epitaxial layer;
a drain drift region with N-type doping formed in the second epitaxial layer, wherein the drain drift region is on part of the P-type buried layer and is in contact with the P-type buried layer;
a P-type well region formed in the second epitaxial layer, wherein the P-type well region is adjacent to the drain drift region;
a body region with P-type doping formed in the second epitaxial layer, wherein the body region is adjacent to the drain drift region;
a drain pickup region with N-type doping formed in the drain drift region; and
a source pickup region with N-type doping and a body pickup region with P-type doping formed in the body region, wherein the source pickup region and the body pickup region are adjacent to each other.

2. The high voltage DMOS of claim 1, further comprising:
a shallow drain region with N-type doping formed in the drain drift region;
wherein the drain pickup region is formed in the shallow drain region.

3. The high voltage DMOS of claim 1, further comprising:
an N-type well region formed in the second epitaxial layer, wherein the N-type well region is adjacent to the P-type well region; and
a link layer with N-type doping formed in the first epitaxial layer, wherein the link layer has a bottom surface contacting with the first buried layer and a top surface contacting with the N-type well region.

4. The high voltage DMOS of claim 1, wherein: the P-type buried layer has forming energy in a range of 200 KeV-1 MeV; and has a dose in a range of 5×10¹¹-4×10¹³ atoms per cubic centimeter.

5. The high voltage DMOS of claim 1, wherein the first epitaxial layer has a thickness in a range of 4 μm-10 μm.

6. The high voltage DMOS of claim 1, wherein the second epitaxial layer has a thickness in a range of 1.2 μm-4.0 μm.

7. The high voltage DMOS of claim 1, further comprising:
a field region formed in the second epitaxial layer;
a thermal oxide field plate formed on part of the drain drift region;
a gate oxide formed on any active area;
a gate poly formed on the gate oxide and on the thermal oxide field plate;
a drain electrode contacted with the drain pickup region; and
a source electrode contacted with the source pickup region and with the body pickup region.

8. A method for forming a high voltage high side DMOS, comprising:
forming an N-type buried layer in a substrate with P-type doping;
forming a first epitaxial layer with P-type on the substrate;
forming a P-type buried layer in the first epitaxial layer, wherein the entire P-type buried layer is on top of and on part of the N-type buried layer;
forming a second epitaxial layer with P-type doping on the first epitaxial layer;
forming a drain drift region with N-type doping in the second epitaxial layer, wherein the drain drift region is on part of the second buried layer;
forming a field region formed in the second epitaxial layer;
forming a thermal oxide field plate on part of the drain drift region;
forming P-type well region and N-type well region in the second epitaxial layer;
forming thin gate oxide on active area of the second epitaxial layer;
forming a gate poly on the thin gate oxide and on the thermal oxide field plate;
forming a body region with P-type doping in the second epitaxial layer, wherein the body region is adjacent to the drain drift region;
forming a shallow drain region with N-type doping in the drain drift region;
includes forming a drain pickup region with N-type doping in the shallow drain region, a source pickup region with N-type doping and a body pickup region with P-type doping in the body region; and
forming a plurality of electrodes contacted with the pickup regions and with the gate poly.

9. The method of claim 8, further comprising:
forming a link layer with N-type doping in the first epitaxial layer, wherein the link layer contacts the N-type buried layer at the bottom side.

10. The method of claim 8, wherein: the P-type buried layer has forming energy in a range of 200 KeV-1 MeV; and has a dose in a range of 5×10¹¹-4×10¹³ atoms per cubic centimeter.

11. The method of claim 8, wherein the first epitaxial layer has a thickness in a range of 4 μm-10 μm.

12. The method of claim 8, wherein the second epitaxial layer has a thickness in a range of 1.2 μm-4.0 μm.
